(19) United States
(12) Patent Application Publication
(10) Pub. No.: US 2007/0008793 A1
(43) Pub. Date: Jan. 11, 2007

(54) Semiconductor apparatus

(75) Inventor: Atsunori Hirobe, Tokyo (JP)

Correspondence Address: FOLEY AND LARDNER LLP;SUITE 500, 3000 K STREET NW, WASHINGTON, DC, 20007, US

(73) Assignee: NEC CORPORATION

(21) Appl. No.: 11/481,184

(22) Filed: Jul. 6, 2006

(30) Foreign Application Priority Data
Jul. 11, 2005 (JP) 2005-201438

(51) Int. Cl. G11C 7/00

(52) U.S. Cl. 365/194

(57) ABSTRACT

Disclosed is an apparatus for detecting power supply dependency and process dependency of a delay circuit to enable control of the delay of the delay circuit and operation acceleration/deceleration. The apparatus includes a first delay circuit receiving a first signal and delaying the first signal received by a preset delay time to output the so delayed signal, a second delay circuit receiving the first signal in common with the first delay circuit and outputting signals of different delay amounts from plural output ends thereof, and a plural number of comparator circuits provided in association with the plural outputs of the second delay circuit, each configured to receive an output of the first delay circuit and a corresponding output of the second delay circuit and to compare the signals received. The delay of the control signal is varied by a variable delay circuit, based on plural outputs of the plural comparator circuits, in order to variably control e.g. the operation timing of a circuit being controlled.

### FIELD OF THE INVENTION

This invention relates to a semiconductor apparatus. More particularly, this invention relates to a circuit that may suitably be applied to control of signal delay in a semiconductor apparatus and semiconductor memory device, such as DRAM (dynamic random-access memory).

### BACKGROUND OF THE INVENTION

With the miniaturization of semiconductor devices and the increase of storage capacity of DRAM, the gate length and the thickness of a gate oxide film of a MOS transistor have been reduced, as a result of which the operating voltage of DRAM has been made progressively lower. An over-drive technique has so far been used for a sense amplifier in order to accelerate the operation of the sense amplifier under a low voltage. For example, if the sense amplifier is composed by a static-type CMOS latch circuit, an external power supply voltage VDD is applied to a source of a P-channel MOS transistor, at an initial phase of the activation timing of the sense amplifier. Then, an internal voltage VDL for a cell array, obtained by stepping down the external power supply voltage VDD, is applied to the source of the P-channel MOS transistor of the sense amplifier to perform the sense operation. For the sense operation in a DRAM device, an internal voltage for a cell array (VDL) is used. In high-speed DRAM devices, a high speed sense operation is achieved by the over-drive technique. As for the over-drive technique, see the disclosure in, for example, Patent Document 1.

Under the current status of use of a low operating voltage, miniaturization and scaling, it is becoming difficult to further reduce the threshold voltage Vt of n-channel MOS transistors and p-channel MOS transistors which constitute a sense amplifier (CMOS static-type latch sense amplifier) and variations in the threshold voltage Vt tend to be increased in production. In light of these, one is compelled to use smaller values of the drain-to-source voltage Vds and the gate-to-source voltage Vgs of an n-channel MOS transistor in the sense amplifier during the cell-H-sense operation, that is, during the sense operation by the sense amplifier of the HIGH data of memory cell.

In the over-drive scheme of the sense amplifier, there is a demand for further acceleration of the drain-to-source voltage Vds and the gate-to-source voltage Vgs of a p-channel MOS transistor of the sense amplifier during the cell-L sense operation, that is, during the operation of sensing the low level data of the memory cell. The cell-L differential potential, that is, the differential potential between a bit line pair, may be enlarged with improvement in the cell capacitance. In addition, with use of a lower operating voltage, the drain-to-source voltage Vds of the n-channel MOS transistor in the sense amplifier during the sense operation tends to b made progressively smaller.

However, the gate-to-source voltage Vgs of the gate-to-source voltage Vgs of the n-channel MOS transistor of the sense amplifier is usually a reference voltage (HVCC) and hence is constant.

Thus, the cell-L sense operation takes more time than the cell-H sense operation. Moreover, even if the n-channel MOS transistor of the sense amplifier is turned on at an early time, “L” charge (charge for setting a cell to the LOW level) needs to be supplied to the cell, and hence there is limitation in driving with the n-channel MOS transistor. There is raised an intrinsic demand for early turning ON of the p-channel MOS transistor of the sense amplifier.

If the power supply voltage, applied to the sense amplifier, is high, the over-drive may be carried out excessively in the sense amplifier, depending on particular setting of the over-drive period.

If conversely the power supply voltage, applied to the sense amplifier, is low, the over-drive is not sufficient. In such case, the n-channel MOS transistor and the p-channel MOS transistor of the sense amplifier may be turned on at a delayed timing, so that a desired characteristic is not accomplished and the sense amplifier executes an erroneous sense operation.

Even supposing that the sense operation is achieved without error, the amount of electric charge, that may be supplied to an I/O line under the condition that the minimum specification value for the high-speed sense characteristic tRCD is met, is evidently smaller than that during the cell-H sense operation, thus possibly leading to cell defect ascribable to failure in a data amplifier, that is, failure in reading LOW level data from a cell.

It is therefore necessary to provide means for properly controlling the over-drive period and the over-drive strength.

In a DRAM, the WL-SE period is predetermined, where the WL-SE period is a time period from the time when a word line for selecting a memory cell is selected to the time when data is output on a bit line and activation of a sense amplifier becomes possible. It is crucial to control this WL-SE period. For example, if, in a status of a high ambient temperature, the delay time of a delay circuit which generates the WL-SE period, becomes shorter, the sense amplifier is activated without waiting for data output from the memory cell for a sufficiently long time. This means that the data efficiency from the memory cell (cell efficiency) is deteriorated and hence the probability is high for a data hold failure (fail in data retention by the cell) to take place. If a sufficiently long WL-SE period is set for avoiding the occurrence of the data hold failure, the delay may become excessively long in case of low ambient temperature, with the result that the sense activation is delayed. Hence, the condition set in the specifications such as an access time for data read cannot be met.

The means for properly controlling the WL-SE period is demanded.

Meanwhile, there is known a configuration in which, for preventing an excessive over-drive, an inverter operated with a power supply voltage (VDD) is used to confer negative delay dependency with respect to the power supply voltage on a delay circuit (Patent Documents 1 and 2). In Patent Document 1, there is provided an inverter as a delay circuit, used in combination with negative dependency of delay of the internal voltage employing the dependency of the substrate voltage on the power supply voltage VDD.

Table 1 shows forward characteristics in which delay time of the delay circuit becomes shorter as the power supply voltage VDD becomes higher. Table 2 shows reverse characteristics in which delay time of the delay circuit becomes shorter as the power supply voltage VDD becomes lower, that is, in which delay time of the delay circuit becomes longer as the power supply VDD becomes higher. Meanwhile, each delay time in Table 1 and Table 2 is approximate value.

TABLE 1

delay time

| | 4 ns | 3 ns |
|---|---|---|
| VDD voltage | 3 V | 3.5 V |

TABLE 2

delay time

| | 1.5 ns | 1.8 ns |
|---|---|---|
| VDD voltage | 3 V | 3.5 V |

On the other hand, the over-drive period is adjusted so that the characteristic will be satisfied on the lower side of the power supply voltage VDD, within the operating range of products. If the sense operation of high-speed characteristic is to be met, a longer over-drive period tends to be used. However, if adjustment is made so that the over-drive period will not be excessive on the higher side of the power supply voltage VDD, the dependency on the power supply voltage VDD will become smaller, thus possibly limiting or setting product characteristics per se.

Moreover, if process variations are taken into account, the process dependency of the over-drive becomes larger than the process dependency of a delay device, as a result of which the high-speed sense operation is limited by the over-drive period.

There has also been known a technique for performing control by replicating the sense operation during the over-drive period (Patent Document 3). In this technique, attention is paid to variations in the capacitance Cd of a bit line, the signal on which is to be amplified by a sense amplifier. Specifically, the capacitance Cd is replicated to detect the charging/discharging state of the capacitance Cd, and the over-drive period of the sense amplifier is controlled accordingly. However, with the Patent Document 3, the delay time is designed to replicate the charging to the Cd of the sense amplifier, while there is no mention made of the dependency on the power supply voltage VDD or on means for preventing quantitatively excess over-drive. Meanwhile, the Patent Document 4 shows the configuration of a delay circuit in which a one-clock period is measured with a delay circuit and a signal which has advanced one clock is taken out from a tap.

[Patent Document 1]

Japanese Patent Kokai Publication No. JP-A-09-120675

[Patent Document 2]

Japanese Patent Kokai Publication No. JP-A-10-242815

[Patent Document 3]

Japanese Patent Kokai Publication No. JP-A-05-062467

[Patent Document 4]

Japanese Patent Kokai Publication No. JP-P2004-064143A

### SUMMARY OF THE DISCLOSURE

As described above, in the conventional over-drive technique, there is presented a problem that, if adjustment is made on the high side of the power supply voltage VDD, there are imposed limitations on the characteristic of DRAM products.

There is also presented a problem that, in case process variations are taken into account, the process dependency of the over-drive becomes greater than the process dependency of the delay unit, such that the sense operation by a sense amplifier is limited by the over-drive period.

Furthermore, the implementation of proper control of the WL-SE period is demanded.

Accordingly, it is an object of the present invention to provide a device for detecting the power supply dependency and process dependency of a delay circuit to control the delay time or to enable acceleration or deceleration of the control operation.

The above and other objects are attained by the present invention, which is summarized substantially as follows:

A semiconductor apparatus according to the present invention comprises first and second delay circuits receiving a first signal in common; said first delay circuit delaying said first signal by a preset delay time and outputting the so delayed signal; said second delay circuit delaying said first signal by respective different delay amounts to output the so delayed signals at a plurality of output ends, respectively; a plurality of comparator circuits provided in association with said plural output ends of said second delay circuit, said comparator circuits each receiving an output of said first delay circuit and a corresponding output of said second delay circuit for comparing the outputs received; and a variable delay circuit receiving a second signal for variably controlling the delay time of said second signal based on outputs of said comparator circuits.

Preferably in the present invention, the comparator circuit comprises a latch circuit. The semiconductor apparatus of the present invention may further comprise a circuit for generating a one-shot pulse signal when the first signal has been delayed the preset delay time by the first delay circuit. The latch circuit may receive the one-shot pulse signal, as an output from the first delay circuit, and latch an output of the second delay circuit, responsive to the one-shot pulse signal.

Preferably in the present invention, the variable delay circuit may include a third delay circuit supplied with the second signal and outputting a plurality of signals, delayed by respective different delay amounts from the second signal, at its plural output ends, and a plurality of switches receiving the outputs of the third delay circuit, and receiving, as switching signals, the outputs of the plural comparator circuits, so as to be on/off controlled. A signal output from one of the switches which is in an on-state may be output as the delayed signal of the second signal.

Preferably in the present invention, the second delay circuit exhibits at least one of power supply voltage dependency of the delay time and temperature dependency of the delay time different from the corresponding dependency of the first delay circuit.

Preferably in the present invention, there may be provided a one-shot pulse generating circuit responsive to a rising edge or a falling edge of the second signal for generating a one-shot pulse, the pulse width of which is determined by the delay time of the variable delay circuit.

Preferably in the present invention, there may be provided a circuit for detecting non-coincidence of outputs of two neighboring ones of the comparator circuits. The variable delay circuit variably controls the delay time of the second signal based on the results of detection of non-coincidence.

Preferably in the present invention, the second signal may be an internal sense start signal and the one-shot pulse generating circuit may output an over-drive signal controlling the over-drive period for the sense operation.

Preferably in the present invention, the second signal may be a sense enable signal and the one-shot pulse generating circuit may output a signal prescribing the WL_SE period which is the time as from selection of a word line until activation of a sense amplifier is enabled.

Preferably in the present invention, an over-drive signal, controlling the over-drive period for the sense operation, may be generated from an edge of the signal prescribing the WL_SE period and an edge of a signal obtained on delaying a control signal activated at a time earlier than the sense enable signal.

Preferably in the present invention, one transistor or a plurality of transistors arranged in parallel are inserted between an external power supply and the sense amplifier, wherein the transistor is on/off controlled by the over-drive signal and connect the external power supply to the sense amplifier during the time the on-time of the transistor.

Preferably in the present invention, at least one transistor may be arranged between an internal power supply and the sense amplifier, wherein the transistor is turned on during the time when the sense amplifier is activated to connect the internal power supply, the voltage of which is lower than the voltage of the external power supply, to the sense amplifier.

The meritorious effects of the present invention are summarized as follows.

According to the present invention, it is possible to detect power supply dependency and process dependency of a delay circuit to control the delay as well as acceleration/deceleration of the operations of a delay circuit

According to the present invention, the delay time of a delay circuit not having power supply voltage dependency is compared to the delay time having power supply voltage dependency. A delay circuit or a driver is controlled in accordance with the results of comparison to select proper control against the operating environment dependency. The present invention may be applied with advantage for controlling the sense timing in a DRAM, in particular for controlling the over-drive timing or the timing of the WL-SE period, or for controlling the potency of the over-drive.

Still other features and advantages of the present invention will become readily apparent to those skilled in this art from the following detailed description in conjunction with the accompanying drawings wherein only the preferred embodiments of the invention are shown and described, simply by way of illustration of the best mode contemplated of carrying out this invention. As will be realized, the invention is capable of other and different embodiments, and its several details are capable of modifications in various obvious respects, all without departing from the invention. Accordingly, the drawing and description are to be regarded as illustrative in nature, and not as restrictive.

### BRIEF DESCRIPTION OF THE DRAWINGS

FIG. 1 is a diagram showing the configuration of an embodiment of the present invention.

FIG. 2 is a diagram showing the configuration of an embodiment of the present invention.

FIG. 3 is a diagram showing the configuration of an embodiment of the present invention.

FIG. 4 is a diagram showing the configuration of an embodiment of the present invention.

FIG. 5 is a timing chart for illustrating the operation of an embodiment of the present invention.

FIG. 6 is a timing chart for illustrating the operation of an embodiment of the present invention.

FIG. 7 is a graph showing power supply dependency of the over-drive period according to an embodiment of the present invention.

FIG. 8 shows the configuration of an over-drive signal generating circuit according to an embodiment of the present invention.

FIG. 9 is a timing chart for illustrating the operation of the over-drive signal generating circuit.

FIG. 10 is a timing chart for illustrating the operation of a circuit for setting the over-drive period.

FIGS. 11A and 11B are schematic views showing the configuration of a sense driver according to an embodiment of the present invention.

FIG. 12 is a schematic view showing the structure of a sense driver according to another embodiment of the present invention.

### PREFERRED EMBODIMENTS OF THE INVENTION

The present invention will be described in detail with reference to the accompanying drawings. The present invention includes means for detecting power supply dependency and process dependency of the delay of internal operations, for determining the sense control, over-drive control and control of the WL-SE period, the control circuitry for accelerating or decelerating one of said sense control, with use of the detected result, and a path for delay propagation.

According to the present invention, an input signal is supplied in common to a fist delay circuit having power supply voltage dependency, and to a second delay circuit, not having power supply voltage dependency, and an output of the first delay circuit is compared with an output of the second delay circuit by a comparator circuit. A target delay unit or a target driver is controlled on the basis of an output signal of the comparator circuit to enable selection of proper control against power supply dependency.

Moreover, according to the present invention, the input signal is supplied in common to the first delay circuit exhibiting temperature dependency and to the second delay circuit not exhibiting temperature dependency, and outputs of the first and second delay circuits are compared with each other. A target delay unit or a target driver is controlled on the basis of an output signal of the comparator circuit to enable selection of proper control against temperature dependency.

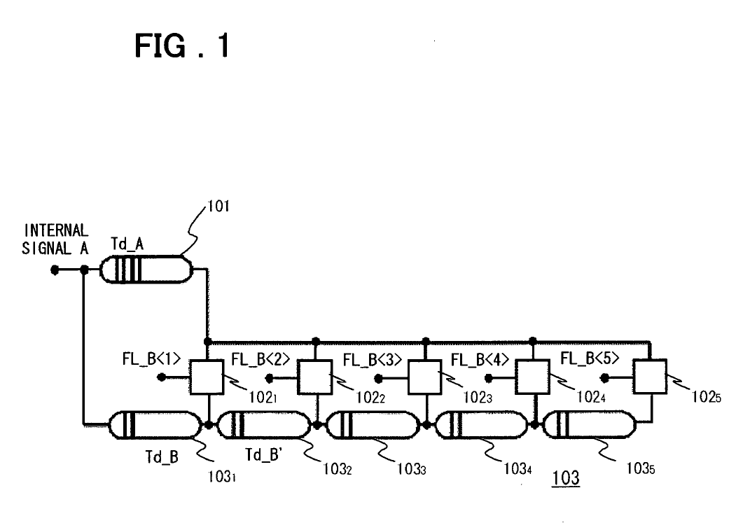

FIG. 1 shows the circuit configuration of an embodiment of the present invention. Referring to FIG. 1, the embodiment includes a delay circuit 101, a delay circuit array 103, made up by cascaded delay circuits 103₁ to 103₅, and a plural number of comparator circuits 102₁ to 102₅. The comparator circuits receive an output of the delay circuit 101 and outputs of the delay circuits 103₁ to 103₅ of respective stages of the delay circuit array 103 for comparing them with each other from stage to stage. The delay circuit 101 and the delay circuit array 103 receive an internal signal A in common. Meanwhile, in FIG. 1, the number of stages of the delay circuits 103₁ to 103₅ of the delay circuit array 103 is five, while the number of the comparator circuits 102₁ to 102₅ is also five. However, the present invention is not limited to the configuration shown in FIG. 1. The comparator circuits are provided in association with the stages of the delay circuit array 103 and the number of the stages of the delay circuit array 103 is arbitrary.

In the delay circuit array 103, composed by the cascade-connected delay circuits 103₁ to 103₅, the delay time of which is not dependent on the external power supply, there may be provided delay circuits having respective delay times different each other, such as Td_B and Td_B′, or the delay times of the delay circuits 103₁ to 103₅ may also be the same.

On the other hand, the delay circuit 101 has the delay time which is dependent on the external power supply. These delay circuits are supplied with an internal signal A in common.

The comparator circuits 102₁ to 102₅ output the results of comparison by codes FL_B<1> to FL_B<5>. Meanwhile, these configuration of comparator circuits as a matter of course impose no particular limitations on the present invention.

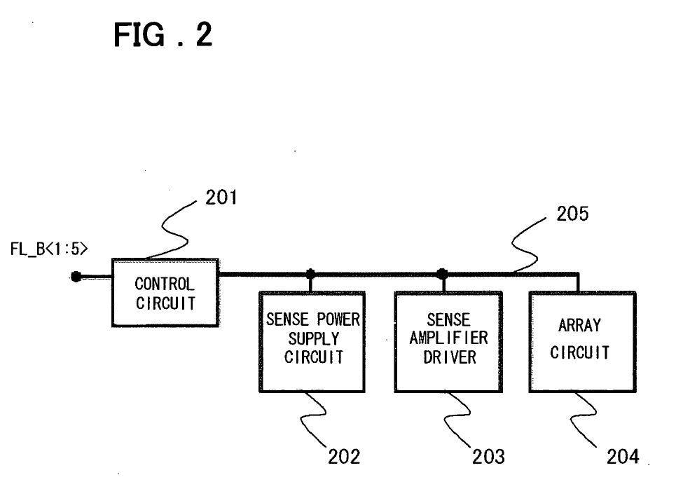

FIG. 2 schematically shows the configuration of a semiconductor memory of an embodiment of the present invention, inclusive of a circuit structure shown in FIG. 1. The outputs FL_B<1> to FL_B<5> from the comparator circuits 102₁ to 102₅ of FIG. 1 are supplied to a control circuit 201 of FIG. 2. The control circuit 201 controls a sense power supply circuit 202, a sense amplifier driver 203 and an array circuit (memory array circuit) 204, based on five-bit signals FL_B<1> to FL_B<5> (FL_B<1:5>).

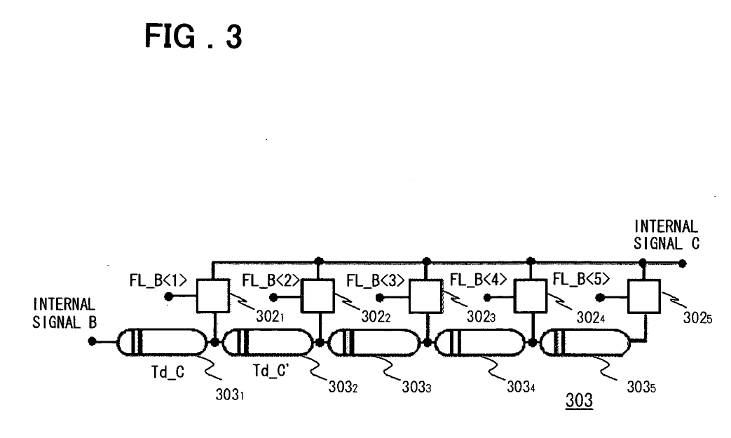

FIG. 3 shows the configuration of a delay circuit (variable delay circuit) provided within each of the sense power supply circuit 202, the sense amplifier driver 203 and the memory array circuit 204 and which variably controls the signal delay time based on the signals FL_B<1:5>. The variable delay circuit of FIG. 3 reproduces the delay detected in FIG. 1. Referring to FIG. 3, the circuit includes switches 302₁ to 302₅, in association with outputs of the delay circuits 303₁ to 303₅ of a delay circuit array 303. The switches 302₁ to 302₅ receive an internal signal B and are turned on/off, respectively, based on the signals FL_B<1> to FL_B<5> supplied from the control circuit 201 of FIG. 2. The signals FL_B<1> to FL_B<5> represent the results of comparison of the comparator circuits 102₁ to 102₅ of FIG. 1. When a relevant one of the signals FL_B<1> to FL_B<5> is “1”, a corresponding one of the switches 302₁ to 302₅ is turned on to output an output of a corresponding one of the delay circuits 303₁ to 303₅ of the delay circuit array 303 as an internal signal C.

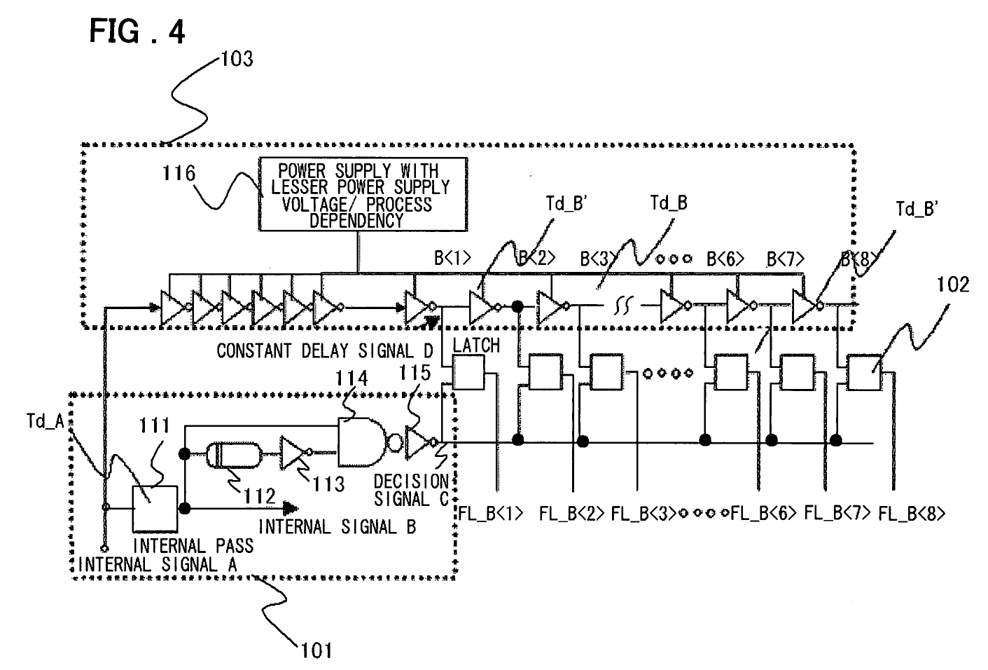

FIG. 4 shows the configuration of an embodiment of the present invention, and specifically shows an illustrative configuration of the delay circuit 101, delay circuit array 103 and the comparator circuit 102. Referring to FIG. 4, the delay circuit 101 includes a delay unit 111 which receives an internal signal A and delays the so received signal by delay time Td_A to output an internal signal B. The internal signal B is supplied to a one-shot pulse generating circuit which comprises a delay circuit 112, an inverter 113, a NAND 114 and an inverter 115. The one-shot pulse generating circuit generates a one-shot pulse (a decision signal C) of a width which continues for a time duration corresponding to the delay time of the delay circuit 112 from the rise transition of the internal signal B. The comparator circuit 102 is composed by a latch circuit receiving, as a sampling clock, the one-shot pulse (decision signal C) output from the delay circuit 101, to latch an output of the delay circuit array 103 responsive to the one-shot pulse. The internal signal B may be supplied as the internal signal B to the delay circuit array 303 of FIG. 3.

The delay circuit array 103, driven by a power supply unit, the supply voltage of which has only low process dependency, includes a delay circuit array, made up by an inverter array, and generates a constant delay signal D, which is obtained on delaying a constant time from the internal signal A. This constant delay signal D is delayed by a plural number of unit delay circuits. Output node signals B<1> to B<8> of the unit delay circuits are latched by eight comparator circuits (latch circuits) 102. These eight comparator circuits (latch circuits) 102 output FL_B<1> to FL_B<8> respectively. It is noted that the unit delay circuits in the delay circuit array 103 are each formed by a one-stage inverter-circuit. For example, there is provided a one-stage inverter between the nodes B<1> and B<2>. However, two stage of inverters are used as a unit delay circuit in order to delay a signal with non-inverting logic. The delay time of the constant delay signal D is set to a value longer than the delay time of the unit delay (resolution) between neighboring ones of the nodes B<1> to B<8>. For example, in an embodiment which will be described later, the unit delay time is 0.5 ns, while the constant delay time D is 7 ns.

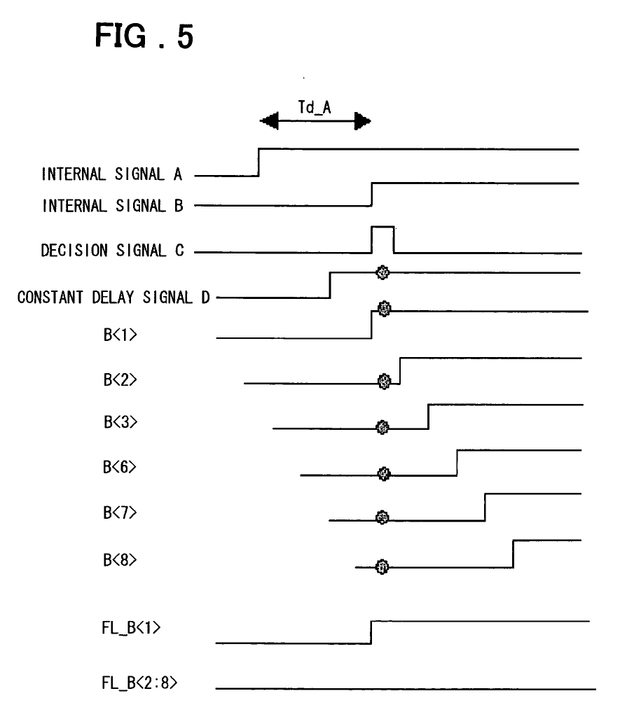

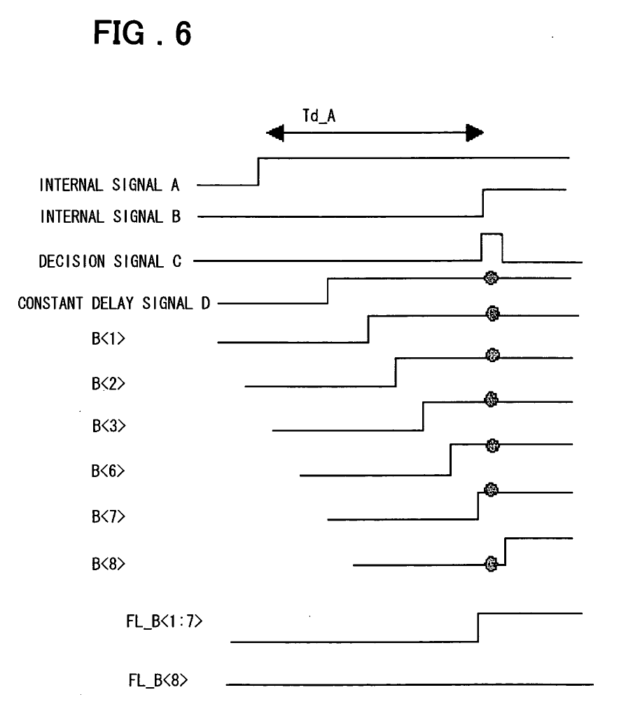

FIGS. 5 and 6 are timing charts for illustrating the operation of the circuit shown in FIG. 4. Meanwhile, in FIGS. 5 and 6, a unit delay circuit of the delay circuit array 103 of FIG. 4 is composed by two stages of inverters. The internal signal B rises after a delay of Td_A, from the rising of the internal signal A. A one-shot pulse of the decision signal C is output on detection of the rising edge of this internal signal B. The comparator circuit (latch) 102 latches the logic value of a relevant one of the nodes B<1> to B<8> with the rising edge of the one-shot pulse. As a result, FL_B<1> is HIGH, while FL_B<2:8> become LOW.

In the case of FIG. 6, Td_A is longer than in the case of FIG. 5, so that the rising of the decision signal C (one-shot pulse) is delayed from that in the case of FIG. 5, such that FL_B<1:7> become HIGH, while FL_B<8> becomes LOW.

The operation and the meritorious effect of the present invention will now be described.

The delay time Td_A, exhibiting power supply voltage-process dependency, is measured by the delay time Td_B, exhibiting small power supply voltage-process dependency. The delay time Td_A, exhibiting power supply voltage-process dependency, may be the delay time from a given command, such as a sense start command, to the activation of a signal for a given internal operation, such as a sense start signal. The delay time of a delay path, exhibiting the power supply voltage-process dependency, is measured appropriately.

The delay time Td_B is divided to uniform or non-uniform time intervals. These intervals are compared with Td_A to generate plural signals FL_B<1:8> for the delay amount of Td_A.

The outputs FL_B<1:8> of the latch circuit 102 are directly output, or converted into encoded data by an encoder, not shown, provided in, for example, a control circuit 201 of FIG. 2. The resulting encoded data are connected to a bus in the circuit. For example, the encoded data are transferred on a bus 205 of FIG. 2 to e.g. the sense power supply circuit 202, sense amplifier driver 203 and to the memory array circuit 204. The sense power supply circuit 202, sense amplifier driver 203 and the memory array circuit 204 decode the signals FL_B<1:8> received, by decoders, not shown, to select a delay path of the variable delay circuit of FIG. 3, such as to generate desired delay time.

In case of controlling the over-drive period of a sense amplifier, for example, the delay path is selected in such a manner that the delay amount will become smaller for a high power supply voltage VDD or for a low threshold value Vt of the MOS transistor.

In similar manner, the drive capability of the over-drive may properly be selected based on FL_B<1:8>. In addition, sense control, for example, control of the WL_SE period, may be made based on FL_B<1:8> in similar manner.

By comparing a delay circuit with zero or only little power supply voltage-process dependency with a given delay circuit, for example, a critical path of a given command, a condition under which sensing is carried out is sampled and the over-drive period and the over-drive capability (sense capability) may be adjusted based on sampled result. By holding the information of measurement of the signal delay of two points in a circuit and processing the sampled results, it is possible to generate desired delay and to perform desired sense control.

It is assumed that the propagation delay time Td_A has the dependency, shown in Table 3, responsive to the low-speed level, a typical (TYP) level and to the high-speed level. The values of the process threshold Vt level and the operating power supply voltage for the respective speed levels are those referred to respective median values.

TABLE 3

| | Td_A | | Vt | Power supply |
|---|---|---|---|---|
| low-speed | 11 | ns | High | low |
| typical | 9 | ns | Medium | medium |
| high-speed | 8 | ns | Low | high |

In FIG. 4, the constant delay signal D of the delay circuit array 103 is set to about 7 ns for the low speed level, typical speed level and for the high speed level. The delay circuit, having the internal power supply as a power supply, for canceling the external power supply voltage dependency, is composed by, for example, an inverter of a logic gate. This delay circuit serves as a reference path against variations in the external power supply. A delay unit or an internal power supply for canceling out process dependency or temperature dependency may be used to serve as reference against process variations or temperature variations.

For constituting comparator circuits (latch circuits) 102 which compare the propagation time of the internal signal B at steps of 0.5 ns, the latch circuits 102 latch the outputs of nodes (B<1:8>) every 0.5 ns delay (Td_B) for the signal D, by the decision signal C. Table 4 shows a list of delays of the nodes B<1> to B<8> for the delay of the constant delay signal D of the delay circuit array 103. Meanwhile, the delay in the delay circuit array 103 does not necessarily have to be divided into equal intervals.

TABLE 4

| B<1> | B<2> | B<3> | B<4> | B<5> | B<6> | B<7> | B<8> |
|---|---|---|---|---|---|---|---|
| 7.5 | 8.0 | 9.0 | 9.5 | 10.0 | 10.5 | 11.0 | 11.5 |

If, in the high-speed level, the propagation time Td from the internal signal A to the internal signal B is about 7.5 ns, the node B<1> (constant delay time D=7 ns) becomes “HIGH” at the rise time of the decision signal C, while the other nodes B<2:8> are LOW (see FIG. 5). The delay amount may be detected by detecting the points of non-coincidence of the outputs of the neighboring comparator circuits 102. If an exclusive OR (EXOR) circuit is used as the non-coincidence detection circuit, EXOR (FL_B<1>, FL_B<2>)=1. The over-drive period may be controlled by changing over the delay in association with the results, responsive to the signal FL_B.

In a case shown in FIG. 6, there is a significant delay of the internal signal in the low-speed level, such that signals FL_B<1> to FL_B<7> are verified to be 1, while the signal FL_B<8> is verified to be zero. EXOR (FL_B<7>, FL_B<8>)=1.

In a case wherein variations in Td_A are significant and become smaller than 7 ns or longer than 11 ns, that is, fall outside the range for decision, such that FL_B<1>=0 or FL_B<1>=1, decision is given for the shortest delay time or for the longest delay time.

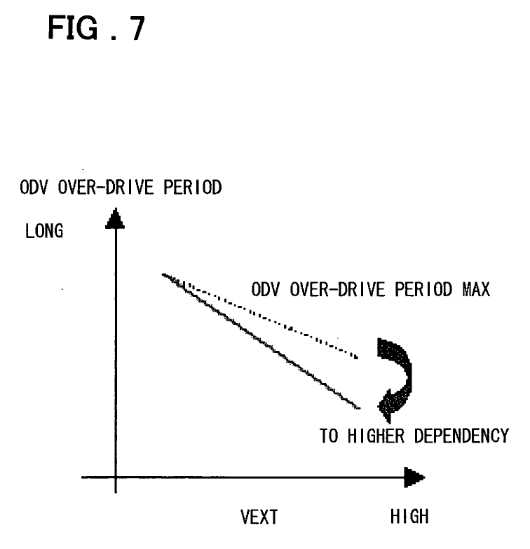

An example of controlling the over-drive signal ODV will now be described, by way of an embodiment of the present invention. According to the present invention, the over-drive period is dependent on an external power supply voltage VEXT more strongly than with the conventional technique. In FIG. 7, the horizontal axis and the vertical axis stand for the external power supply voltage VEX and the over-drive period, respectively. With an embodiment of the present invention, shown by a solid line in FIG. 7, the rate of change (tilt) of the over-drive period with respect to the external power supply voltage is higher than that of the conventional technique indicated by a broken line in FIG. 7.

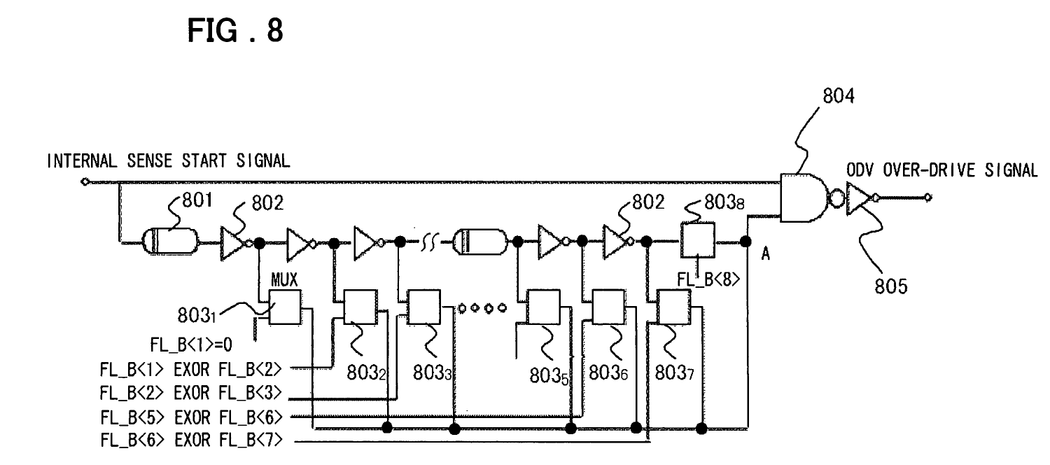

FIG. 8 shows the configuration of a circuit for generating an over-drive signal ODV from an internal sense start signal. The circuit includes a delay circuit 801, a set of inverters 802 and switches (MUXs) 803₁ to 803₈. The first MUX 863₁ receives the signal FL_B<1> of FIG. 4 as a control signal, the second MUX 8032 receives an EXOR of the signals FL_B<1> and FL_B<2> of FIG. 4 as a control signal, and the third MUX 803₂ receives an EXOR of the signals FL_B<2> and FL_B<3> of FIG. 4 as a control signal. The seventh MUX 8037 receives an EXOR of the signals FL_B<6> and FL_B<7> of FIG. 4 as a control signal as a control signal, and the eighth MUX 803₈ receives the signal FL_B<8> of FIG. 4 as a control signal. The circuit of FIG. 8 also includes a NAND circuit 804, which receives an internal sense drive signal and an output of a selected one of the first to eighth MUXs 803₁ to 803₈, as inputs, and an inverter 805 receiving an output of the NAND circuit 804, as an input. The NAND circuit 804 and the inverter 805 generate a one-shot pulse, in synchronization with the rise transition of the internal sense drive signal. The pulse width of the one-shot pulse is prescribed by the MUXs. That is, the delay corresponding to the result of the delay detection of FIG. 4 is reproduced in the pulse width.

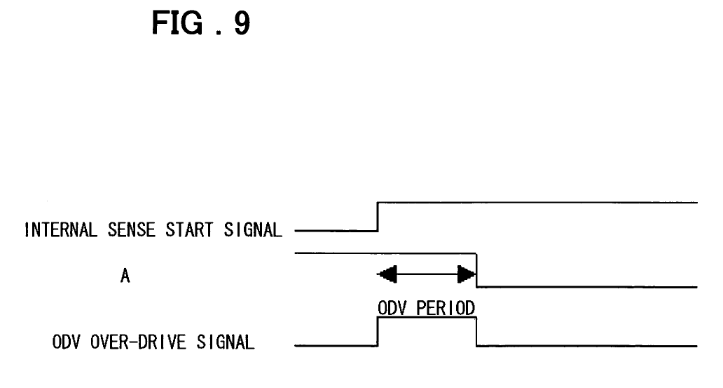

FIG. 9 shows waveforms of the internal sense start signal, signal A and the over-drive signal ODV. The over-drive period can be controlled to a desired length by changing over the delay path, determining the over-drive period, that is, the delay path determining the pulse width of the one-shot pulse, by the switches (MUXs) 803₁ to 803₈, depending on the signals FL_B<1:8>. In the configuration of FIG. 8, delay paths are changed over so that the delay path selected will exhibit the dependency shown in FIG. 7, that is, the high external power supply dependency.

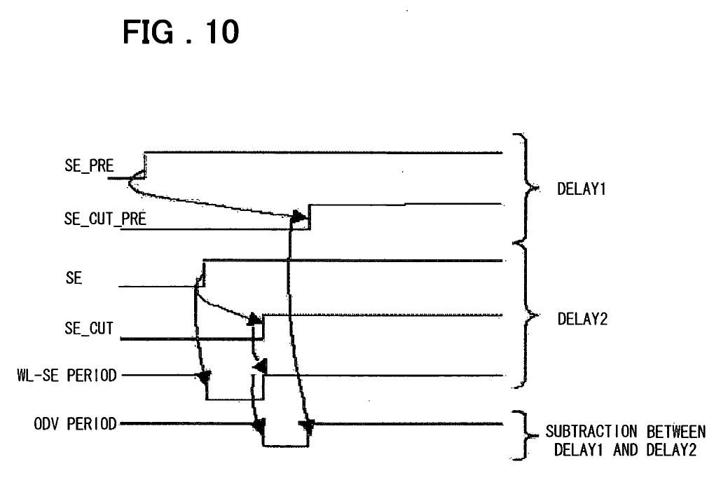

In another example of the present invention, for determining the WL-SE period, the signals FL_B<1:8>, are supplied to the MUXs 803₁ to 803₈ of FIG. 8 so as to exhibit inverse external power supply voltage dependency. This inverse external power supply voltage dependency is controlled such as to change over the stages of the delay paths. In this case, the internal sense start signal of FIG. 8 is used as the sense amplifier enable signal SE. FIG. 10 is a timing-chart illustrating the operation in determining the WL-SE period. From a signal SE_PRE, temporally earlier than the sense amplifier enable signal SE, a signal SE_CUT_PRE of a delay DELAY1, dependent on the external power supply voltage VEXT, is generated. Also, from the sense amplifier enable signal SE, delay DELAY2 for the WL-SE period is generated. From the rising edge of the WL-SE period and from the rising edge of the signal SE_CUT_PRE, an over-drive signal ODV controlling the over-drive period, is generated. Thus, by combining the delay DELAY1 and the delay DELAY2, in this manner, the over-drive period, exhibiting stronger dependency on the external power supply voltage VEXT, may be generated from the path dependent on the external power supply voltage VEXT and from the path inversely dependent on the external power supply voltage VEXT. In FIG. 10, the signal SE_PRE may be the same as the signal SE.

In case of the external power supply voltage VEXT being high, the WE-SE period becomes longer, while the propagation delay as from the rising of the signal SE_PRE until the rising of the signal SE_CUT_PRE becomes shorter.

Thus, when the external power supply voltage VEXT is raised, the over-drive period, which is generated from the rising edge of the WL-SE period and the rising edge of the signal SE_CUT_PRE, is further reduced, so that the external power supply voltage dependency is further increased (see FIG. 7).

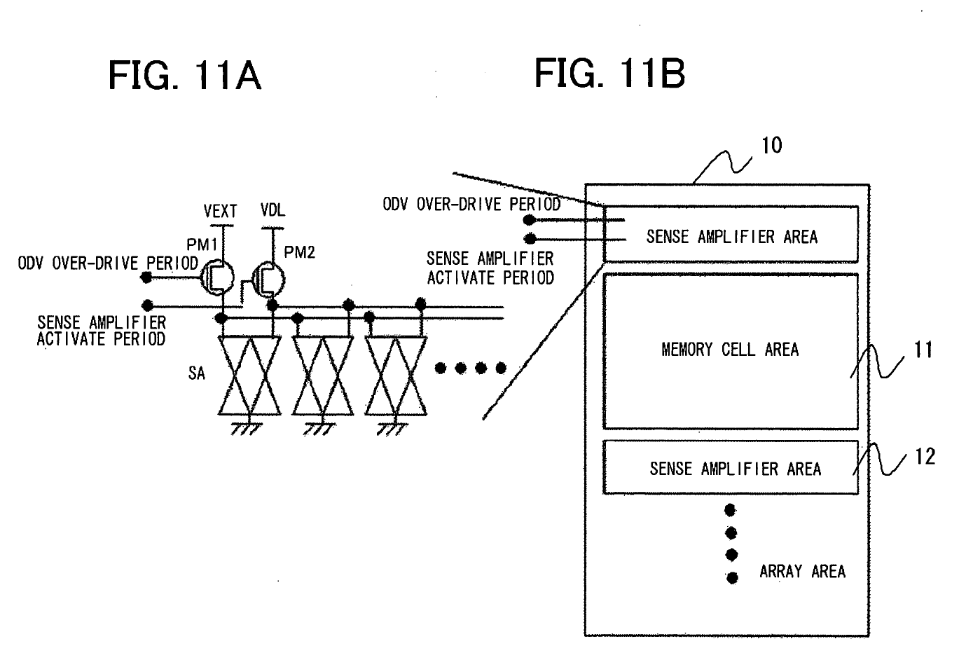

FIG. 11A schematically shows the configuration of a sense amplifier region of a DRAM 10 shown in FIG. 11B. In the configuration shown in FIG. 11B, the DRAM 10 includes a sense amplifier area 12 on each side of a memory cell area (cell array) 11. The sense amplifier area 12 includes a sense amplifier connected to a bit line of the memory cell area (cell array) 11.

Referring to FIG. 11A, the external power supply voltage VEXT and an internal array power supply voltage (internal stepped-down power supply voltage produced by stepping down the VEXT) are connected to each sense amplifiers SA, via p-channel MOS transistors PM1 and PM2, for use for an over-drive operation and for a normal sense amplifier activating operation, respectively. In the following, the over-drive control will be described, while the control for the ground (GND) side and the control for the general sense amplifier control are dispensed with.

In the present embodiment, an output signal of the inverter 805 of FIG. 8 is used as the signal ODV controlling the over-drive period, and which is output to the gate of the transistor PM1 of FIG. 11A.

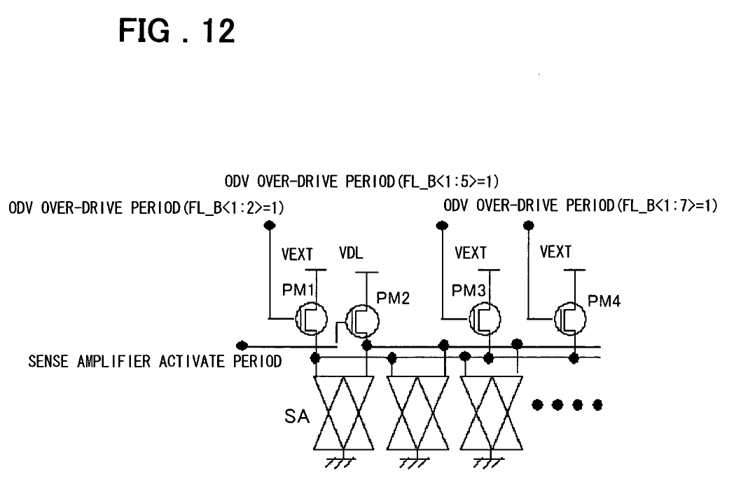

Alternatively, a plural number of p-channel MOS transistors PM1, PM3 and PM4, may be connected between the external power supply voltage VEXT and the sense amplifier SA, as shown in FIG. 12. To the gates of these transistors PM1, PM3 and PM4 are supplied signals for the over-drive periods (F L_B<1:2>=1), (F L_B<1:5>=1) and (F L_B<1:7>=1), respectively. It is noted that, during the over-drive period, the external power supply voltage VEXT is supplied to the sense amplifier via p-channel MOS transistors. Specifically, the potency of the over-drive (driving capability) itself may be adjusted by controlling the on/off of the plural p-channel MOS transistors with the use of the signals (FL_B<1:8>). This parallel array of the plural transistors may similarly be used for the p-channel MOS transistors connecting to the internal array power supply VDL. During the over-drive period, the output of the power supply circuit itself is output as the external power supply voltage VEXT. The internal array power supply VDL adjusts the potency of the output as well. The results of decision may be encoded/decoded in any desired suitable manner depending on the process and the array configuration.

During the over-drive period, the drive capability of the over-drive is selected in any desired suitable manner. For example, if the power supply voltage VDD is low and the process or the temperature is not favorable for the sense operation of the sense amplifier, the over-drive period and the over-drive capability are enlarged. In the reverse case, a shorter over-drive period is used to reduce the over-drive capability.

Thus, in the present embodiment, desired control operations may readily be selected, depending on the logic of a decoder, decoding the results of sampling (FL_B<1:8>) obtained by the latch circuit 102 of FIG. 4, for example. The environment of the sense operation by the sense amplifier is detected, using delay elements which may be produced with simple and easy design, and the over-drive period and capability (sense capability) may be adjusted, based on the detected result. Of course, the present invention is not limited to generation of control signals for adjusting the over-drive period as well as over-drive capability (sense capability) and may be applied to optional circuitry designed to generate the delay as power supply voltage dependency, for example, is taken into account.

Although the present invention has so far been described with reference to the preferred embodiments, the present invention is not limited to the particular configurations of these embodiments. It will be appreciated that the present invention may encompass various changes or corrections such as may readily be arrived at by those skilled in the art within the scope and the principle of the invention.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A semiconductor apparatus comprising:
first and second delay circuits receiving a first signal in common;
said first delay circuit delaying said first signal by a preset delay time and outputting the so delayed signal;
said second delay circuit delaying said first signal by respective different delay amounts and outputting the so delayed signals at a plurality of output ends thereof, respectively;
a plurality of comparator circuits provided in association with said plural output ends of said second delay circuit, said comparator circuits each receiving an output of said first delay circuit and a corresponding output of said second delay circuit for comparing the outputs received; and
a variable delay circuit receiving a second signal for variably controlling the delay time of said second signal based on outputs of said comparator circuits.

2. The semiconductor apparatus according to claim 1, wherein said comparator circuit comprises a latch circuit.

3. The semiconductor apparatus according to claim 1, wherein said second delay circuit comprises a delay circuit array including a plurality of delay circuits cascade-connected and having outputs thereof connected to said output ends, respectively; and wherein
the delay time of each delay circuit of said delay circuit array is obtained by division of the delay time of said first delay circuit.

4. The semiconductor apparatus according to claim 2, further comprising a circuit for generating a one-shot pulse signal when said first signal has been delayed said preset delay time by said first delay circuit;
said latch circuit receiving said one-shot pulse signal, as an output from said first delay circuit, and latching an output of said second delay circuit, responsive to said one-shot pulse signal.

5. The semiconductor apparatus according to claim 1, wherein a signal obtained on delaying said first signal said preset delay time by said first delay circuit is supplied as said second signal to said variable delay circuit.

6. The semiconductor apparatus according to claim 1, wherein said variable delay circuit includes:
a third delay circuit receiving said second signal, and delaying said second signal by respective different delay amounts to output the so delayed signals at a plurality of output ends thereof, respectively; and
a plurality of switches receiving said outputs of said third delay circuit, and receiving, as switching signals, the outputs of said plural comparator circuits; said plurality of switches being on/off controlled by said switching signals;
a signal output from one of said switches which is in an on-state being output as a delayed signal of said second signal.

7. The semiconductor apparatus according to claim 1, wherein said second delay circuit has at least one of power supply voltage dependency of the delay time and temperature dependency of the delay time, different from the corresponding dependency of said first delay circuit.

8. The semiconductor apparatus according to claim 1, wherein the process dependency of the power supply voltage of said second delay circuit is relatively smaller than the corresponding dependency of said first delay circuit.

9. The semiconductor apparatus according to claim 1, further comprising a one-shot pulse generating circuit responsive to a rising edge or a falling edge of said second signal for generating a one-shot pulse, the pulse width of which is determined by the delay time of said variable delay circuit.

10. The semiconductor apparatus according to claim 1, further comprising a circuit for detecting non-coincidence of outputs of two neighboring ones of said comparator circuits;
said variable delay circuit variably controlling the delay time of said second signal based on the results of detection of non-coincidence.

11. The semiconductor apparatus according to claim 9, wherein the semiconductor apparatus comprises a semiconductor memory;
said second signal is an internal sense start signal which is for staring the sense operation of a sense amplifier; and wherein
said one-shot pulse generating circuit outputs an over-drive signal controlling the over-drive period for the sense operation of the sense amplifier.

12. The semiconductor apparatus according to claim 9, wherein the semiconductor apparatus comprises a semiconductor memory;
said second signal is a sense enable signal which is for controlling to enable/disable a sense amplifier; and wherein
said one-shot pulse generating circuit outputs a signal prescribing the WL_SE period which is the time period from the selection of a word line to the activation of the sense amplifier being enabled.

13. The semiconductor apparatus according to claim 12, wherein an over-drive signal controlling the over-drive period for the sense operation, is generated from an edge of said signal prescribing the WL_SE period and an edge of a signal obtained on delaying a control signal activated at a time earlier than said sense enable signal.

14. The semiconductor apparatus according to claim 11, further comprising a transistor or a plurality of transistors arranged in parallel between an external power supply and said sense amplifier; said transistor being on/off controlled by said over-drive signal and connecting said external power supply to said sense amplifier during the on-time thereof.

15. The semiconductor apparatus according to claim 14, further comprising a transistor or a plurality of transistors arranged in parallel between an internal power supply and said sense amplifier; said transistor being turned on during the time when said sense amplifier is activated to connect said internal power supply to said sense amplifier, the voltage of said internal power supply being lower than that of said external power supply.

16. A semiconductor memory apparatus comprising:
first and second delay circuits receiving a first signal in common;
said first delay circuit delaying said first signal by a preset delay time and outputting the so delayed signal;
said second delay circuit delaying said first signal by respective different delay amounts and outputting the so delayed signals at a plurality of output ends thereof, respectively;
a plurality of comparator circuits provided in association with said plurality output ends of said second delay circuit, said comparator circuits each receiving an output of said first delay circuit and a corresponding output of said second delay circuit for comparing the signals received; and
a circuit for variably controlling at least one of an operation timing, an operation time period and a driving capability in at least one of a sense power supply circuit, a sense amplifier driver circuit and a memory array circuit, based on the results of comparison in said comparator circuits.

17. The semiconductor memory apparatus according to claim 16, wherein said variably controlling circuit includes:
a variable delay circuit receiving a second signal which is for variably controlling the delay time of said second signal based on outputs of said comparator circuits; and
a one-shot pulse generating circuit responsive to a rising edge or a falling edge of said second signal for generating a one-shot pulse, the pulse width of which is determined by the delay time of said variable delay circuit;
said second signal being an internal sense start signal which is for staring the sense operation of a sense amplifier;
said one-shot pulse generating circuit outputting an over-drive signal controlling the over-drive period for the sense operation of the sense amplifier.

18. The semiconductor memory apparatus according to claim 16, wherein said variably controlling circuit includes:
a variable delay circuit receiving a second signal which is for variably controlling the delay time of said second signal based on outputs of said comparator circuits; and
a one-shot pulse generating circuit responsive to a rising edge or a falling edge of said second signal for generating a one-shot pulse, the pulse width of which is determined by the delay time of said variable delay circuit;
said second signal being a sense enable signal which is for controlling to enable/disable a sense amplifier;
said one-shot pulse generating circuit outputs a signal prescribing the WL_SE period which is the time period from the selection of a word line to the activation of the sense amplifier being enabled.
